(19) United States
(12) Patent Application Publication
(10) Pub. No.: US 2016/0221097 A1
(43) Pub. Date: Aug. 4, 2016

(54) COATINGS TO ENHANCE WETTING, ADHESION AND STRENGTH

(71) Applicant: Sandia Corporation, Albuquerque, NM (US)

(72) Inventors: Daniel Kammler, Albuquerque, NM (US); David P. Adams, Albuquerque, NM (US)

(21) Appl. No.: 14/923,031

(22) Filed: Oct. 26, 2015

Related U.S. Application Data
(60) Provisional application No. 62/109,435, filed on Jan. 29, 2015.

(51) Int. Cl. B23K 1/00; C04B 41/89; C04B 41/50; B23K 35/30; C04B 41/87; C23C 14/34; C23C 14/10; C04B 41/83; C04B 41/48

(52) U.S. Cl. CPC B23K 1/0006; C04B 41/83; C04B 41/89; C04B 41/5035; C04B 41/4853; C04B 41/87; C23C 14/34; C23C 14/10; B23K 35/3006

(57) ABSTRACT

Technologies for enhancing the wetting and adhesion of materials to a ceramic surface are described herein. In a general embodiment, a silicon dioxide film is applied to a ceramic surface that is then joined to another surface by brazing with an active braze filler metal. In another example, the silicon dioxide film is applied to a ceramic surface of a device that is then potted in an epoxy potting material.

### RELATED APPLICATION

This application claims priority to U.S. Provisional Patent Application No. 62/109,435, filed on Jan. 29, 2015, and entitled “COATINGS TO ENHANCE WETTING, ADHESION AND STRENGTH”, the entirety of which is incorporated herein by reference.

### STATEMENT OF GOVERNMENTAL INTEREST

This invention was developed under Contract DE-AC04-94AL85000 between Sandia Corporation and the U.S. Department of Energy. The U.S. Government has certain rights in this invention.

### BACKGROUND

Ceramic materials are used for a wide range of applications in a variety of different fields. In many of these applications, devices or components with ceramic surfaces are joined to, bonded to, or encased in, other materials in order to improve certain characteristics of the ceramic or to integrate the devices or components into larger systems. When devices or components with ceramic surfaces (or devices or components made entirely of a ceramic) are joined to other devices or components by brazing, the behavior of a filler metal in the braze controls the quality, strength, and seal of the bond (referred to as a braze joint). Likewise, when a ceramic is encased in an epoxy to enhance its durability in various applications, the uniform spreading of the epoxy over the ceramic surface and the strength of the bond of the epoxy to the ceramic determine suitability of the epoxy as a protectant.

### SUMMARY

Technologies for improving wetting and adhesion performance of various materials to a ceramic surface are described herein. In a general embodiment, a silicon dioxide coating is applied to a ceramic surface prior to joining the ceramic surface to a metal surface or another ceramic surface through an active braze process. The silicon dioxide coating acts to improve the wetting performance of a braze filler metal that is applied to the ceramic surface compared to when the braze filler is directly applied to the ceramic surface. In another embodiment, the silicon dioxide coating is applied to a component with a ceramic surface prior to potting the component in an epoxy. In such an embodiment, the silicon dioxide acts to improve wetting of the epoxy over the ceramic surface of the component compared to when the epoxy is directly applied to the ceramic surface. The silicon dioxide further acts to improve adhesion of the epoxy to the ceramic surface compared to when the epoxy is directly applied to the ceramic surface.

Additional features and advantages are described herein, and will be apparent from the following Detailed Description and the figures.

### BRIEF DESCRIPTION OF THE DRAWINGS

FIG. 1 is a flow diagram that illustrates an exemplary methodology for coating a ceramic surface with a silicon dioxide film.

FIG. 2 is a diagram of an exemplary system that facilitates applying a silicon dioxide coating to a ceramic braze surface prior to brazing.

FIG. 3 is a diagram that illustrates two exemplary braze joints showing wetting of a filler metal when a silicon dioxide film is applied to a ceramic braze surface.

FIG. 4 is a diagram that illustrates four exemplary ceramic braze surfaces showing wetting of a filler metal when a silicon dioxide film is applied at different thicknesses.

FIG. 5 is a flow diagram that illustrates an exemplary methodology for applying silicon dioxide to a ceramic surface.

FIG. 6 is a diagram that illustrates two exemplary ceramic surfaces showing wetting of an epoxy potting material when a silicon dioxide film is applied to the ceramic surface.

FIG. 7 is a diagram of an exemplary system that facilitates applying a silicon dioxide coating to a ceramic surface of a device prior to potting the device with an epoxy.

FIG. 8 is a diagram showing sample results of an experiment measuring strength of a braze joint and thickness of a silicon dioxide film applied to a ceramic braze surface.

FIG. 9 is a diagram showing sample results of an experiment measuring wetting area of an active braze filler metal and thickness of a silicon dioxide film applied to a ceramic braze surface.

### DETAILED DESCRIPTION

Technologies pertaining to using silicon dioxide films to improve wetting and adhesion of materials to a ceramic surface (compared to when a braze filler metal or an epoxy is directly applied to the ceramic surface) are disclosed herein. When brazing is used to join a ceramic surface of a component to a metal surface or to another ceramic surface, the ceramic surface or surfaces generally must be metallized in order for a braze filler metal, which is used to join the two surfaces, to flow and make a clean, sealed braze joint. In a non-active braze, this is accomplished through additional processing steps taken prior to brazing. A common process for metallizing the ceramic surface in a non-active braze comprises the steps of applying a slurry or screen-printed paste of a metal, commonly molybdenum and manganese, and firing the component in a high-temperature (e.g., 1400-1600° C.) furnace prior to the braze.

An active braze, by contrast, eliminates the need for a separate metallizing process prior to brazing by including a few percent of a reactive metal (e.g., zirconium, titanium, hathium, etc.) in the braze filler metal, which is commonly composed primarily of less reactive metals like silver, gold, nickel, copper, etc. In an example, the active braze filler metal comprises 97% silver, 2% zirconium, and 1% copper. The reactive metal components of the braze filler metal can react with the ceramic braze surface to form a layer to which the remaining metal components of the braze filler metal will bond. A disadvantage of active brazing, as contrasted with non-active brazing using a metallization pre-processing step, is that the active braze filler metal generally has poorer wetting performance near its liquidus temperature than in the non-active braze. Wetting and spreading behavior has an impact on expelling of trapped gases (that would otherwise cause voiding), joint thickness, and creation of a hermetic seal at the joint.

Wetting of the braze filler metal is a function of the temperature of the braze; however, increasing temperature of the braze far above its liquidus temperature is energy-intensive and may be undesirable for a variety of processing reasons (e.g. vaporization of the silver in the 97% silver, 2% zirconium, and 1% copper braze filler metal, excessive reaction with a base metal in a ceramic-to-metal joint, etc.).

Wetting of a traditional (i.e., non-active) braze alloy on a metal surface is described by Young's equation:

$$cos {θ}_{0} = \frac{{σ}_{SV} - {σ}_{SL}}{{σ}_{LV}} \qquad Equation 1$$

where σ_{SV} is solid/vapor surface tension, σ_{SL} is solid/liquid surface tension, σ_{LV} is liquid/vapor surface tension, and θ₀ is a liquid metal contact angle. Additional terms must be added to Young's equation to describe the wetting of an active braze on a ceramic material. Young's equation can be modified by adding terms that account for a change in interfacial energy when an initial ceramic surface is replaced by an interfacial reaction layer (which is formed by reaction between the active braze filler metal and the ceramic substrate) and a change in free energy per unit area resulting from the reaction of the active braze filler metal with the ceramic substrate. These modifications result in the following:

$$cos {θ}_{min} = cos {θ}_{0} - \frac{Δ {σ}_{r}}{{σ}_{LV}} - \frac{Δ {G}_{r}}{{σ}_{LV}} \qquad Equation 2$$

In Equation 2, Δσᵣ is a change in surface tension when the initial ceramic surface is replaced with the interfacial reaction layer. The term ΔGᵣ is a change in free energy per unit area from the reaction of the materials in the active braze filler metal and the ceramic substrate near the interface.

It is possible to modify the second additional term (ΔG_{r/σLV}) by changing the chemical makeup of the substrate with which the active braze is reacting (e.g., by replacing Al₂O₃ with silicon dioxide, because silicon dioxide is more easily reduced than Al₂O₃). Prior experiments, however, have suggested that this term is less important to determining wetting behavior than the first additional term (Δνᵣ/σ_{LV}), which is governed by formation of reactants between active braze constituent elements and substrate constituent elements. In an example, an active braze filler metal comprising 97% silver, 2% zirconium, and 1% copper is brazed on a diamonite substrate, and a silicon dioxide coating improves wetting of the active braze filler metal. This is believed to be a result of reactants that form when the zirconium in the braze filler metal reacts with the silicon dioxide-coated diamonite, which significantly alter the Δνᵣ/σ_{LV} term in Equation 2 above.

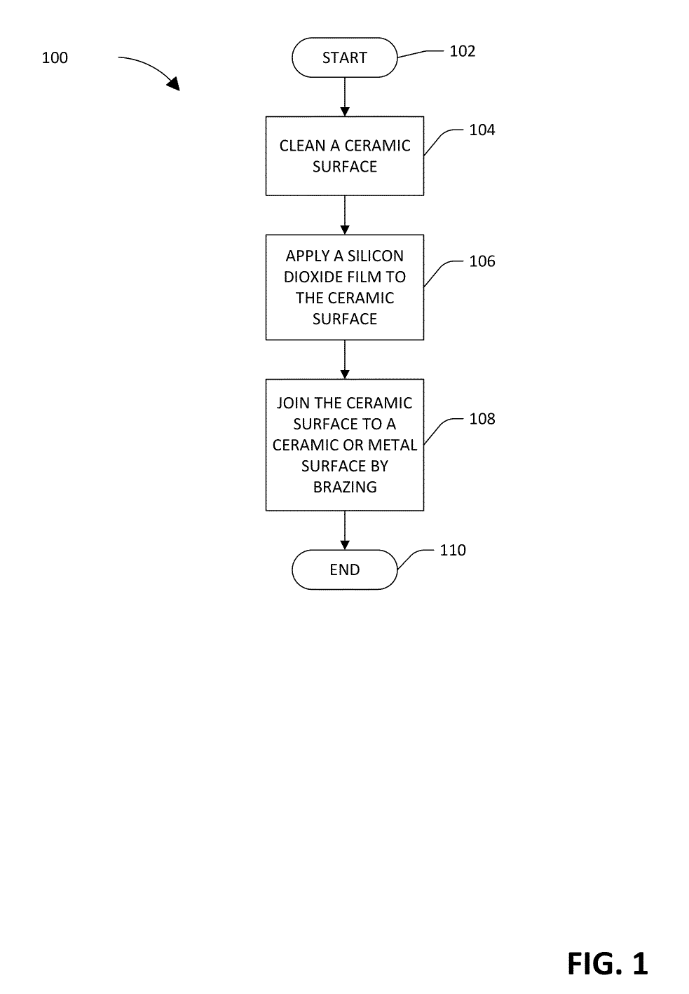

Referring now to FIG. 1, an exemplary methodology 100 for coating a ceramic braze surface with a silicon dioxide film is illustrated. As will be described in greater detail below, coating the ceramic braze surface with a silicon dioxide film has been found to improve wetting behavior of the active braze filler metal compared to when the active braze filler metal is applied directly to the ceramic surface (with no silicon dioxide film). The methodology begins at 102, and at 104 a ceramic braze surface is cleaned prior to application of the silicon dioxide film. In an example, the ceramic braze surface can comprise a debased alumina. For instance, the ceramic braze surface can be of a material that is about 94% alumina such as diamonite or 94ND10. In another example, the cleaning process can include cleaning with an ethanol solution, followed by drying in a nitrogen atmosphere, and final cleaning with an argon plasma.

At 106, the silicon dioxide film is applied to the ceramic braze surface. In an example, the silicon dioxide can be deposited by sputter deposition onto the braze surface in an argon-ambient atmosphere at a pressure of 10 mTorr with a deposition rate of 150 angstroms per minute. In another example, the film may be applied using chemical vapor deposition, atomic layer deposition, or dip coating. The silicon dioxide film can be applied to the ceramic braze surface to have a thickness between 2,000 and 20,000 angstroms. Application of the silicon dioxide film in this thickness range has been observed to improve the wetting behavior of the active braze filler metal (compared to when the active braze filler metal is applied directly to the braze surface), with wetting generally increasing as the thickness of the coating is increased. In certain applications, a mask may be used to target deposition of the silicon dioxide film, such that the silicon dioxide film is applied only to a desired portion of the ceramic braze surface. At 108 the joint is brazed. In an example, the active filler metal used in brazing the joint is 97% silver, 2% zirconium, and 1% copper. In another example, the joint can be brazed at a temperature that is proximate to the liquidus temperature of the filler metal in an inert argon atmosphere. For instance, the joint can be brazed at a temperature between the liquidus temperature of the filler metal and 10 degrees Celsius above the liquidus temperature of the filler metal in an inert argon atmosphere. In another example, the joint can be brazed at a temperature between the liquidus temperature of the filler material and 100 degrees Celsius above the liquidus temperature of the filler material in an inert argon atmosphere. The methodology 100 completes at 110.

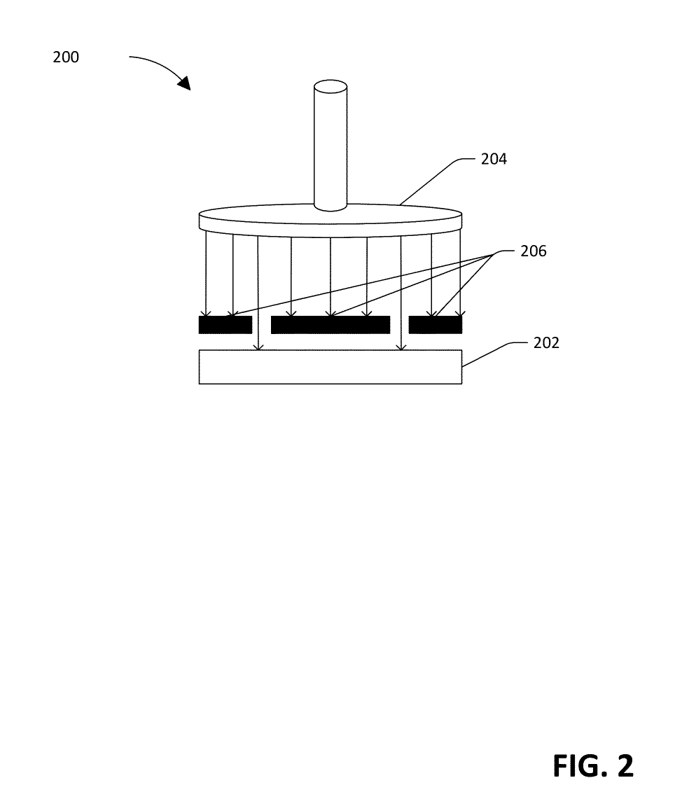

With reference to FIG. 2, an exemplary system 200 that facilitates applying a silicon dioxide film to a ceramic braze surface 202 is illustrated. The system 200 includes a deposition system 204, the ceramic braze surface 202, and a shadow mask 206 that can be used to target deposition of the silicon dioxide film in applications in which it is undesirable to enhance wetting across the entire ceramic braze surface 202. In an example, the deposition system 204 is an RF sputter deposition system that uses an RF plasma to apply 85 W to a 3-inch silicon dioxide target, whereupon silicon dioxide molecules are ejected from the target and deposited on the ceramic braze surface 202.

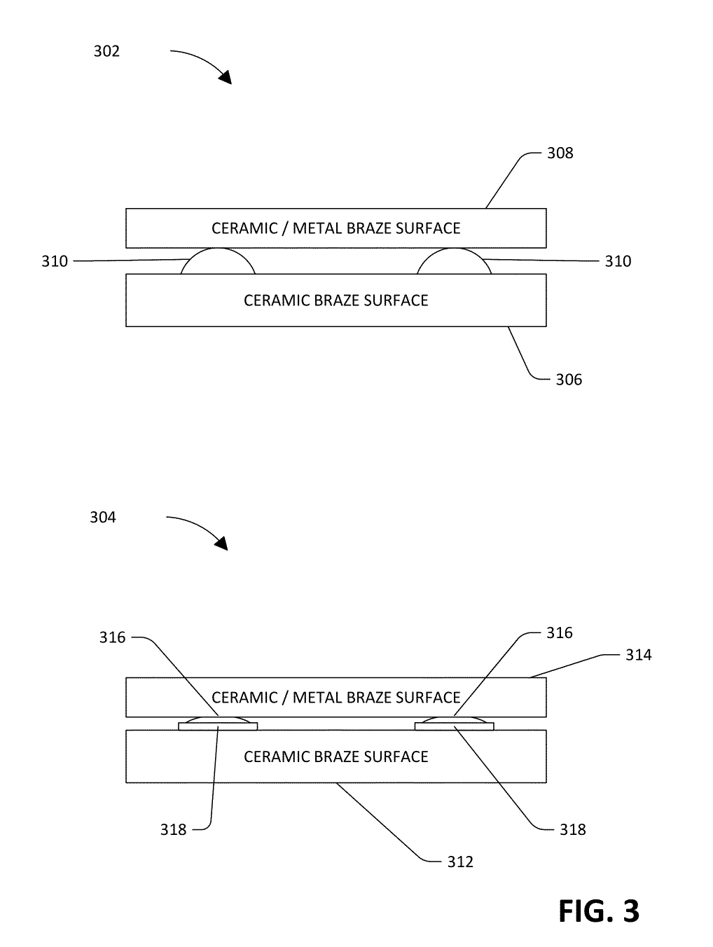

Referring now to FIG. 3, illustrations of two exemplary braze joints 302 and 304 are shown. The first braze joint 302 comprises a first ceramic braze surface 306, a second braze surface 308 that is either ceramic or metal, and an active braze filler metal 310. The second braze joint 304 also comprises a first ceramic braze surface 312, a second braze surface 314 that is either ceramic or metal, and an active braze filler metal 316. The second braze joint 304 further comprises a silicon dioxide film 318 applied over a portion of the ceramic braze surface 312. As shown, the active braze filler metal 316 in the braze joint 304 with the silicon dioxide coating 318 wets and spreads more than the active braze filler metal 310 in the braze joint 302 without the film. The improved wetting of the active braze filler metal 316 can enable greater flexibility in design of components and manufacturing processes by allowing joints to be brazed at temperatures nearer to the liquidus temperature of the active braze filler metal 316, while still producing uniform thickness across the joint 304 and smooth fillets at an edge of the joint 304 as a result of the capillary action that is enabled.

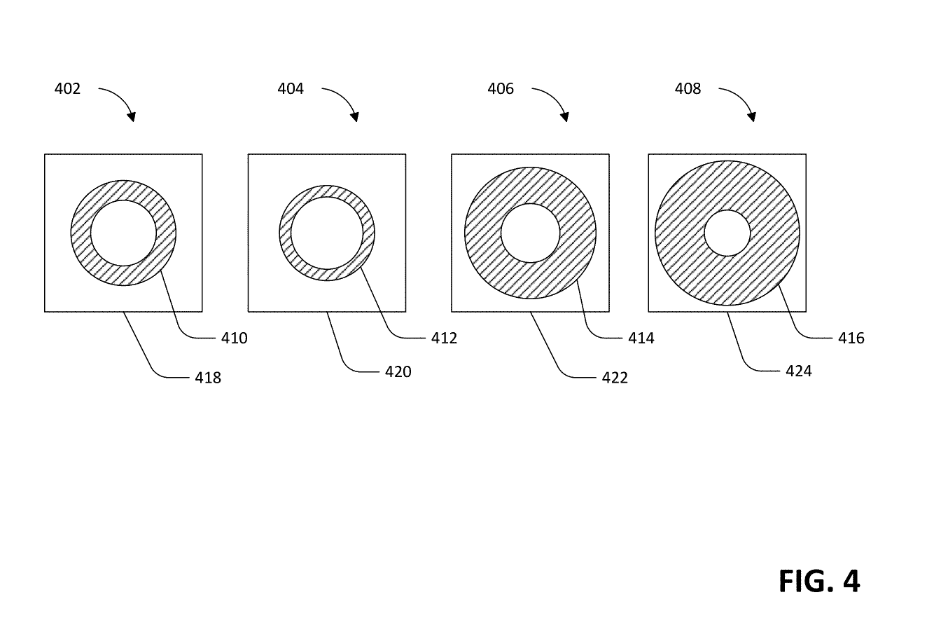

Referring now to FIG. 4, four illustrations 402-408 that show wetting performance of an active braze filler metal when a silicon dioxide film is applied to a ceramic braze surface are shown. The illustrations 402-408 each show an active braze filler metal 410-416 applied on a ceramic braze surface 418-424. In the illustration 402, the active braze filler metal 410 is unreacted (i.e., has not been brazed) and shows an initial application area of the active braze filler metal 412-416 in each of the remaining illustrations 404-408 in which the active braze filler metal 412-416 has already been brazed. The illustration 404 shows wetting performance of the active braze filler metal 412 on the ceramic surface 420 with no silicon dioxide film applied. As shown, the active braze filler metal 412 recedes from the initial application area of the active braze filler metal (as shown in illustration 402) when a silicon dioxide film is not applied. By contrast, the illustration 406 shows that when a silicon dioxide film is applied to the ceramic surface 422 at a thickness of, for example, 2000 angstroms, the active braze filler metal 414 spreads to fill a larger area than the initial application area as shown in illustration 402. The illustration 408 shows that a silicon dioxide film applied at an even greater thickness, for example 20,000 angstroms, further increases the area over which the active braze filler metal 416 spreads.

A silicon dioxide coating can also be used to enhance wetting of an epoxy used as a potting material to encapsulate a device having a ceramic surface. Potting a device can improve its durability, resistance to shock, electrical insulation, etc., and therefore potting is useful in numerous applications such as high voltage electrical devices, dental and other prostheses, high voltage vacuum tube devices, etc. In these and other applications, it is desirable that the epoxy coat the device surface closely and completely, and adhere strongly to the surface. In an example, the metal oxides in a glassy alumina material are terminated with M—O—, M—OH²⁺, or M—OH neutral bonds at the surface, where M is a metal cation. The type of cation (e.g., silicon or aluminum) and the pH of the surface influence the nature and properties of this termination. Coating the surface with the silicon dioxide coating can enhance both the wetting and adhesion of an epoxy potting material by modifying the silicon to aluminum ratio at the surface, thus modifying the terminations of the metal oxides.

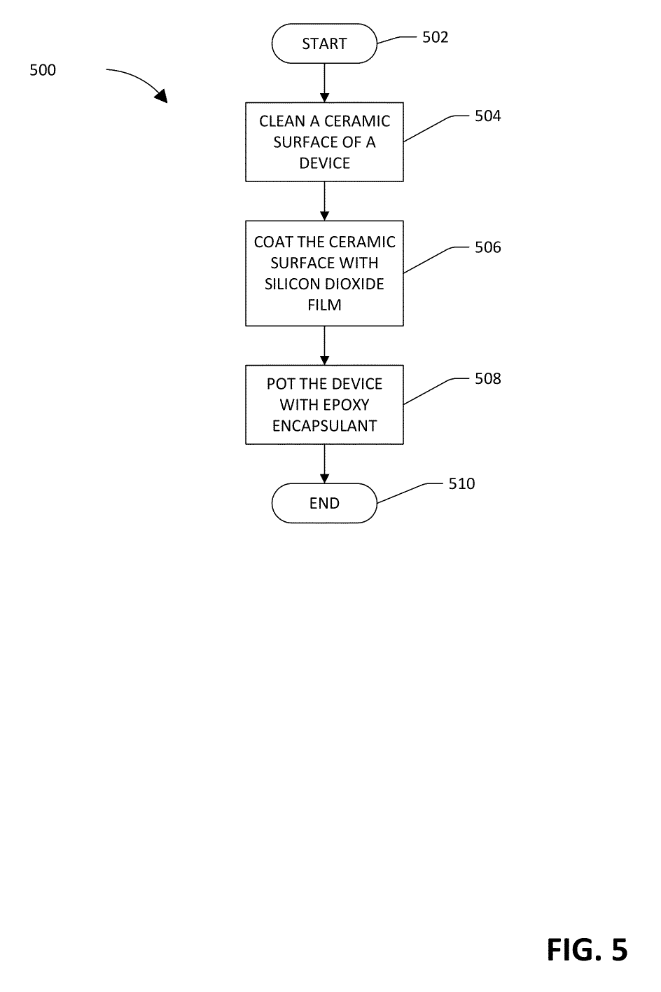

FIG. 5 illustrates an exemplary methodology 500 for coating a ceramic surface with a silicon dioxide film prior to applying an epoxy to the ceramic surface for potting. The methodology 500 begins at 502 and at 504 a ceramic device surface is cleaned to remove surface impurities and debris. In an example, the ceramic surface can be a 94% alumina with 6% intergranular glassy phase such as diamonite. In another example, the cleaning process can include cleaning with an ethanol solution and drying in a nitrogen atmosphere, cleaning with an argon plasma controlled by a Kaufman ion source, etc.

At 506, the ceramic surface of the device is coated with the silicon dioxide film, wherein the film can be applied through a variety of techniques (e.g., RF sputter deposition, dip coating, chemical vapor deposition, etc.). In an example, the film is applied by RF sputter deposition in an argon atmosphere with ambient pressure of 10 mTorr at a rate of 150 angstroms per minute. The thickness of the silicon dioxide film is varied based upon the uniformity of the film deposition and the surface roughness of the ceramic. In an example, the film is applied to a thickness of about 2000 angstroms to a ceramic surface of about 2 micron average roughness. At 508, an epoxy potting encapsulant is applied to the surface coated with the silicon dioxide film. In an example, the epoxy can be bisphenol A diglycidyl ether with a diethanolamine curative agent. The methodology 500 then ends at 510.

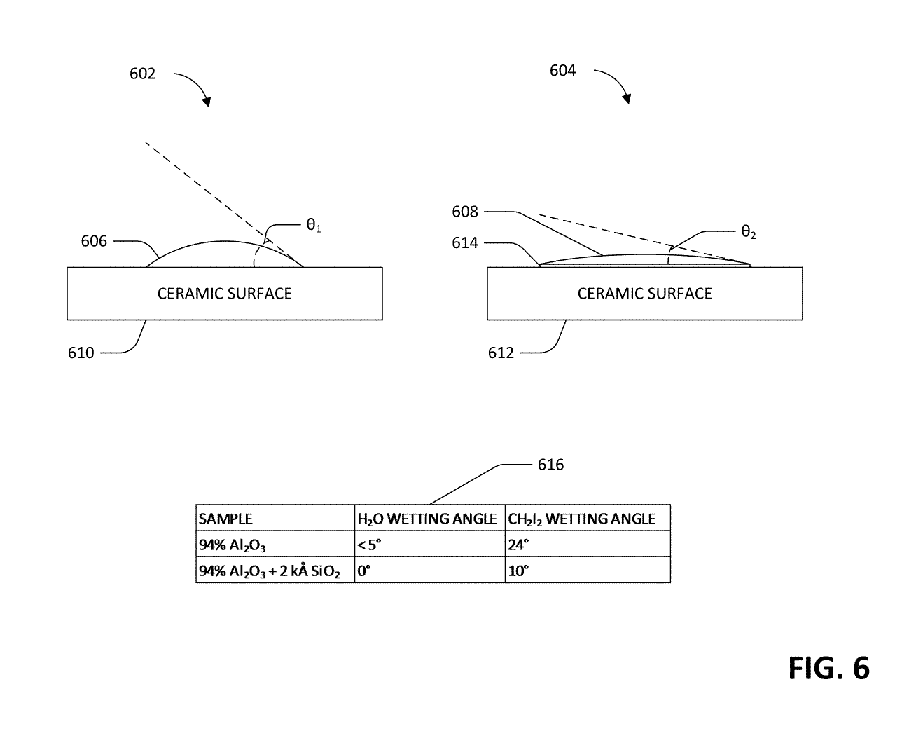

Referring now to FIG. 6, two exemplary illustrations 602 and 604 of wetting performance of epoxies 606 and 608 on ceramic surfaces 610 and 612 are shown. The illustration 602 shows the wetting performance of the epoxy 606 on the uncoated ceramic surface 610 as measured by a wetting angle θ₁. The illustration 604 shows the wetting performance of the epoxy 608 on the ceramic surface 612 coated with a silicon dioxide film 614, as measured by a wetting angle θ₂. The illustrations 602 and 604 demonstrate the improved wetting performance of the epoxy 608 when the silicon dioxide film 614 is applied to the ceramic surface 612. A chart 616 is shown that contains experimental data that suggests the improved wetting performance of epoxies and other materials when a silicon dioxide film is applied to a ceramic surface.

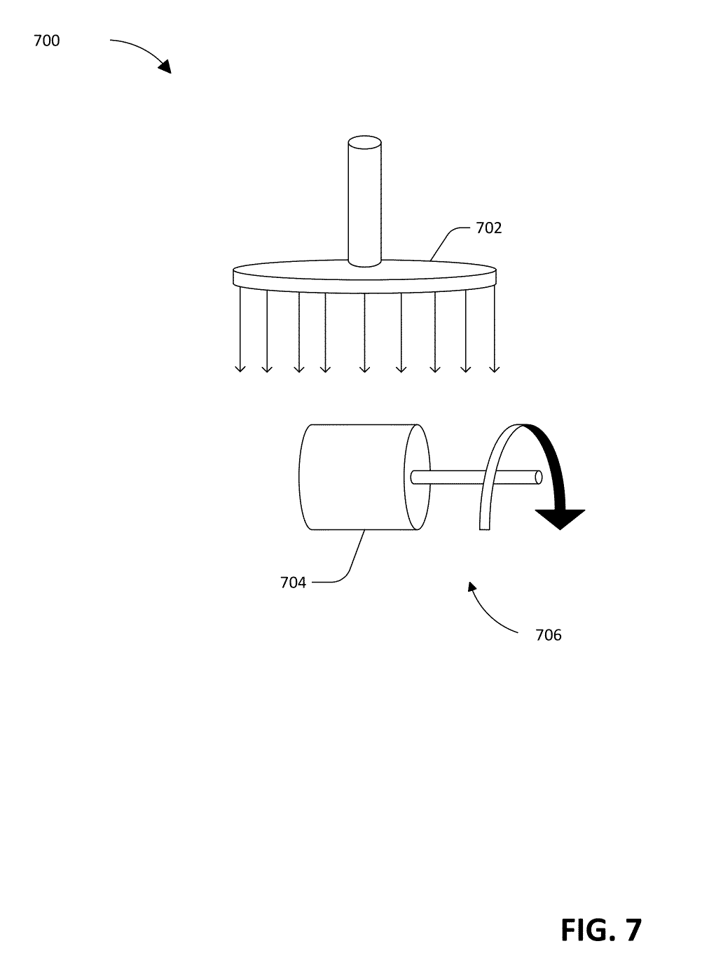

Referring now to FIG. 7, an exemplary system 700 that facilitates application of a silicon dioxide film to a ceramic surface of a device is illustrated. The system includes a deposition system 702 that deposits the silicon dioxide coating on the ceramic surface 704 of the device 706. In the exemplary system 700 shown, the device 706 can be rotated to ensure that the coating is applied uniformly across the surface of the device 706. Applying the coating uniformly helps to ensure uniform performance of the epoxy potting material and helps prevent localized delamination of the epoxy from the ceramic surface of the device 706 as a result of non-uniform adhesion strength.

### Experimental Results

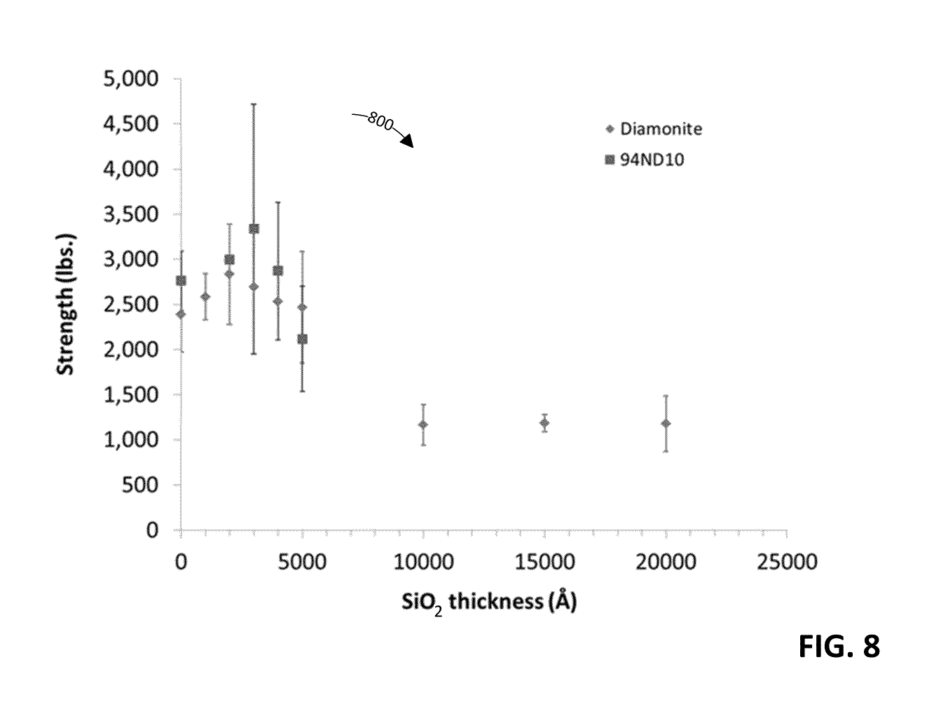

FIG. 8 is a chart 800 that illustrates measured strength versus thickness of silicon dioxide film applied to a ceramic surface of a device, where the strength is indicative of strength of a bond between the device and another device (having a metallic surface). The chart 800 indicates that average strength of the bond increases for both diamonite and 94ND10 when the thickness of the film is between about 2000 and 3000 Angstroms.

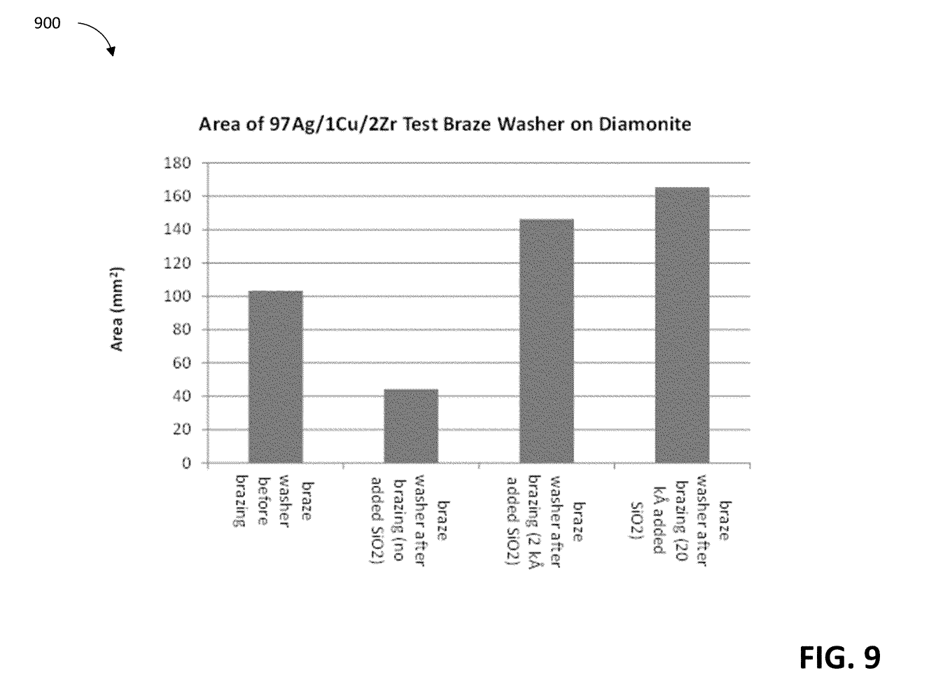

FIG. 9 is a chart 900 that illustrates results of an experiment measuring wetting area of active braze filler metal washers on a ceramic surface. In the experiment, identical active braze filler metal washers are placed on diamonite substrates with and without silicon dioxide coatings of different thicknesses. The chart 900 shows that the area of the original braze washer before brazing is 103 mm². The chart 900 further shows that after brazing the braze washer on the diamonite substrate without a silicon dioxide coating, the area of the braze washer decreases to 44 mm². In the absence of a silicon dioxide film on the diamonite substrate, the braze washer reduces its contact with the underlying diamonite substrate, consistent with illustration 404 of FIG. 4. However, the chart 900 indicates that when 2000 Å of silicon dioxide is added to the diamonite substrate prior to brazing, the area of the braze washer increases from 103 mm² to 146 mm², consistent with illustration 406 of FIG. 4. Moreover, when 20,000 Å of silicon dioxide is added to the diamonite substrate prior to brazing, the chart 900 indicates that the area of the braze washer increases from 103 mm² to 165 mm² consistent with 408 of FIG. 4.

As used herein, the term “or” is intended to mean an inclusive “or” rather than an exclusive “or.” That is, unless specified otherwise, or clear from the context, the phrase “X employs A or B” is intended to mean any of the natural inclusive permutations. That is, the phrase “X employs A or B” is satisfied by any of the following instances: X employs A; X employs B; or X employs both A and B. In addition, the articles “a” and “an” as used in this application and the appended claims should generally be construed to mean “one or more” unless specified otherwise or clear from the context to be directed to a singular form. Additionally, as used herein, the term “exemplary” is intended to mean serving as an illustration or example of something, and is not intended to indicate a preference, and the term “about” refers to a range of 10% of the value to which the term applies.

All patents, patent applications, publications, technical and/or scholarly articles, and other references cited or referred to herein are in their entirety incorporated herein by reference to the extent allowed by law. The discussion of those references is intended merely to summarize the assertions made therein. No admission is made that any such patents, patent applications, publications or references, or any portion thereof, are relevant, material, or prior art. The right to challenge the accuracy and pertinence of any assertion of such patents, patent applications, publications, and other references as relevant, material, or prior art is specifically reserved.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

What has been described above includes examples of one or more embodiments. It is, of course, not possible to describe every conceivable modification and alteration of the above devices or methodologies for purposes of describing the aforementioned aspects, but one of ordinary skill in the art can recognize that many further modifications and permutations of various aspects are possible. Accordingly, the described aspects are intended to embrace all such alterations, modifications, and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

What is claimed is:

1. A method for improving wetting and adhesion of an epoxy potting material to a ceramic surface of a device, the method comprising:
applying a silicon dioxide coating to the ceramic surface of the device; and
potting the device in an epoxy.

2. The method according to claim 1, wherein the ceramic surface comprises a debased alumina.

3. The method according to claim 2, wherein the debased alumina comprises 94% alumina.

4. The method according to claim 3, wherein the debased alumina is diamonite.

5. The method according to claim 1, wherein the epoxy comprises:
bisphenol A diglycidyl ether; and
a diethanolamine curative.

6. The method according to claim 1, wherein applying the silicon dioxide coating to the ceramic surface of the device comprises depositing a silicon dioxide film to the ceramic surface by RF sputter deposition.

7. The method according to claim 1, wherein the silicon dioxide coating is applied to a thickness of between 2000 and 3000 Angstroms.

8. A method for improving wetting of an active braze filler metal, the method comprising:
applying a silicon dioxide film to a ceramic brazing surface of a device, the ceramic brazing surface comprising alumina; and
actively brazing the device to a second device, wherein actively brazing the device to the second device comprises:
placing a filler metal adjacent to the silicon dioxide film; and
brazing the device to the second device at about a liquidus temperature of the filler metal.

9. The method of claim 8, wherein the alumina is a debased alumina.

10. The method of claim 9, wherein the second device has a brazing surface, the brazing surface of the second device comprises a nickel-cobalt ferrous alloy.

11. The method of claim 10, wherein the nickel-cobalt ferrous alloy is diamonite.

12. The method of claim 8, wherein the ceramic brazing surface comprises 94% alumina.

13. The method of claim 12, wherein the ceramic brazing surface is diamonite.

14. The method of claim 8, wherein the filler metal comprises zirconium.

15. The method of claim 8, wherein the filler metal is an alloy comprising:
97% silver;
2% zirconium; and
1% copper.

16. The method of claim 8, wherein applying the silicon dioxide film to the ceramic brazing surface of the first device comprises applying the silicon dioxide film to have a thickness between about 2,000 angstroms and about 3,000 angstroms.

17. The method of claim 8, wherein applying the silicon dioxide film to the ceramic brazing surface comprises depositing the silicon dioxide film using RF sputter deposition in an argon ambient atmosphere.

18. A method of active brazing, the method comprising:
applying a silicon dioxide film to a first debased alumina braze surface; and
joining a second braze surface to the first debased alumina braze surface with an active filler metal by brazing.

19. The method of claim 18, wherein the silicon dioxide film is applied by sputter deposition.

20. The method of claim 18, wherein the silicon dioxide film is applied by dip coating.
